(19) United States
(12) Patent Application Publication
(10) Pub. No.: US 2024/0161829 A1
(43) Pub. Date: May 16, 2024

(54) MEMORY DEVICE RELATED TO A PROGRAM OPERATION, METHOD OF OPERATING THE MEMORY DEVICE, AND STORAGE DEVICE INCLUDING THE MEMORY DEVICE

(71) Applicant: SK hynix Inc., Icheon-si Gyeonggi-do (KR)

(72) Inventors: Hyung Jin CHOI, Icheon-si Gyeonggi-do (KR); Gwi Han KO, Icheon-si Gyeonggi-do (KR); Chan Sik PARK, Icheon-si Gyeonggi-do (KR)

(73) Assignee: SK hynix Inc., Icheon-si Gyeonggi-do (KR)

(21) Appl. No.: 18/194,468

(22) Filed: Mar. 31, 2023

(30) Foreign Application Priority Data
Nov. 11, 2022 (KR) 10-2022-0150647

(51) Int. Cl. G11C 16/10; G11C 11/56; G11C 16/08; G11C 16/24; G11C 16/34

(52) U.S. Cl. CPC G11C 16/10; G11C 11/5628; G11C 11/5671; G11C 16/08; G11C 16/24; G11C 16/3459

(57) ABSTRACT

Provided herein is a memory device for performing a program operation, a method of operating the memory device, and a storage device having the memory device. The method of operating a memory device includes receiving a first data bit among a plurality of data bits to be stored in each of a plurality of memory cells from a memory controller, performing a program voltage apply operation on the plurality of memory cells based on the first data bit, and receiving a second data bit among the plurality of data bits from the memory controller while performing the program voltage apply operation.

### CROSS-REFERENCE TO RELATED APPLICATION

The present application claims priority under 35 U.S.C. § 119(a) to Korean patent application number 10-2022-0150647 filed on Nov. 11, 2022, in the Korean Intellectual Property Office, the entire disclosure of which is incorporated by reference herein.

### BACKGROUND

### 1. Technical Field

Various embodiments of the present disclosure generally relate to a semiconductor device, and more particularly to a memory device related to a program operation and a storage device including the memory device.

### 2. Related Art

A storage device is a semiconductor device which stores data under the control of a host device such as a computer or a smartphone. The storage device may include a memory device in which data is stored and a memory controller which controls the memory device.

The memory device may include a nonvolatile memory device. The nonvolatile memory device may be a memory device in which stored data is retained even when the supply of power is interrupted. Examples of the nonvolatile memory device may include a read only memory (ROM), a programmable ROM (PROM), an electrically programmable ROM (EPROM), an electrically erasable and programmable ROM (EEPROM), and a flash memory.

Meanwhile, the memory device may receive a plurality of data bits from the memory controller during a program operation. Here, because the plurality of data bits are sequentially received, the time required for the program operation may include the time required to receive the plurality of data bits.

### SUMMARY

An embodiment of the present disclosure may provide for a method of operating a memory device. The method may include receiving a first data bit among a plurality of data bits to be stored in each of a plurality of memory cells from a memory controller, performing a program voltage apply operation on the plurality of memory cells based on the first data bit, and receiving a second data bit among the plurality of data bits from the memory controller while performing the program voltage apply operation.

embodiment of the present disclosure may provide for a method of operating a memory device. The method may include receiving a first data bit among a plurality of data bits to be stored in each of a plurality of memory cells from a memory controller; receiving a second data bit among a plurality of data bits to be stored in each of a plurality of memory cells from a memory controller after receiving the first data bit; performing a program voltage apply operation on the plurality of memory cells based on the first data bit and the second data bit; and receiving a third data bit among the plurality of data bits from the memory controller while performing the program voltage apply operation.

An embodiment of the present disclosure may provide for a memory device. The memory device may include a plurality of memory cells, each configured to store a plurality of data bits, a peripheral circuit configured to perform a plurality of program loops on the plurality of memory cells, and a program operation controller configured to control the peripheral circuit to receive one or more data bits among the plurality of data bits from a memory controller, perform a first program loop among the plurality of program loops based on the one or more data bits, and receive remaining data bits, other than the one or more data bits, among the plurality of data bits from the memory controller while the first program loop is being performed.

An embodiment of the present disclosure may provide for a storage device. The storage device may include a memory device including a plurality of memory cells, and a memory controller configured to transmit a program command, an address, and a first data bit for the plurality of memory cells to the memory device, and transmit a second data bit to the memory device while the memory device is programming the first data bit to memory cells corresponding to the address among the plurality of memory cells in response to the program command.

### BRIEF DESCRIPTION OF THE DRAWINGS

FIG. 1 is a flowchart illustrating a method of operating a memory device according to an embodiment of the present disclosure.

FIG. 2 is a diagram illustrating a memory device according to an embodiment of the present disclosure.

FIG. 3 is a diagram illustrating an example of a program operation according to an embodiment of the present disclosure.

FIG. 4 is a diagram illustrating an example in which a plurality of data bits are received according to an embodiment of the present disclosure.

FIG. 5 is a diagram illustrating an example of a program operation according to an embodiment of the present disclosure.

FIG. 6 is a diagram illustrating an example in which a plurality of data bits are received according to an embodiment of the present disclosure.

FIG. 7 is a diagram illustrating a storage device according to an embodiment of the present disclosure.

### DETAILED DESCRIPTION

Specific structural or functional descriptions in the embodiments of the present disclosure introduced in this specification or application are provided as examples to describe embodiments according to the concept of the present disclosure. The embodiments according to the concept of the present disclosure may be practiced in various forms, and should not be construed as being limited to the embodiments described in the specification or application.

Various embodiments of the present disclosure are directed to a memory device having improved time required to receive a plurality of data bits, a method of operating the memory device, and a storage device having the memory device.

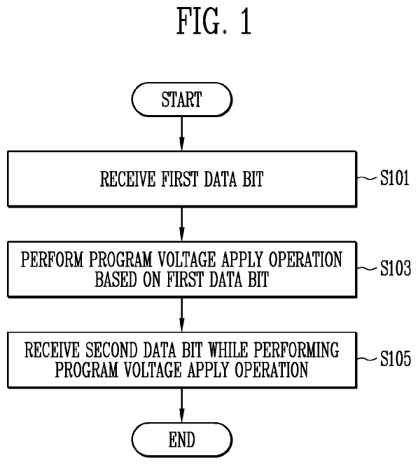

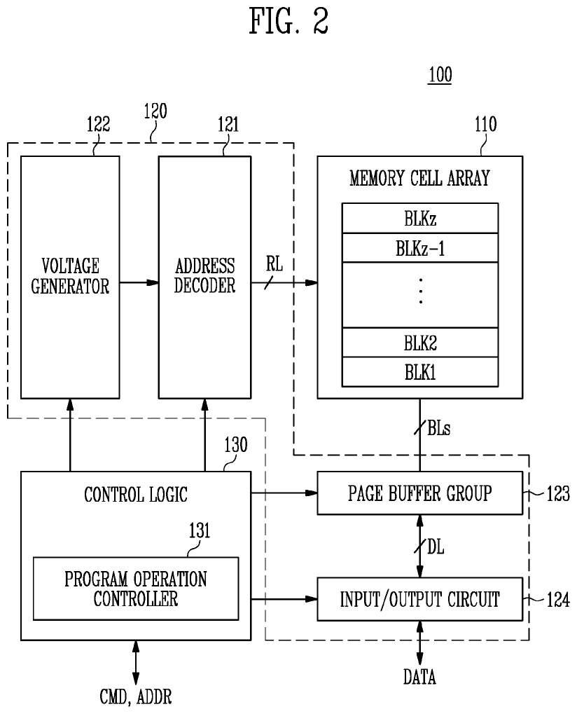

FIG. 1 is a flowchart illustrating a method of operating a memory device according to an embodiment of the present disclosure. The method of FIG. 1 may be performed by a memory device 100 which stores data. The memory device 100 will be described later with reference to the following FIG. 2.

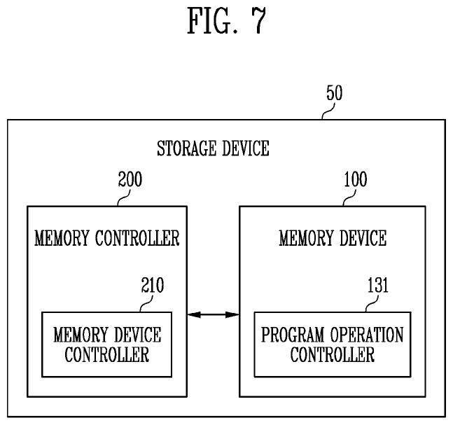

Referring to FIG. 1, at step S101, the memory device 100 may receive a first data bit from a memory controller 200. The first data bit may be any one of a plurality of data bits to be stored in each of a plurality of memory cells. Meanwhile, the memory controller 200 will be described later with reference to the following FIG. 7.

At step S103, the memory device 100 may perform a program voltage apply operation on the plurality of memory cells based on the first data bit.

At step S105, the memory device 100 may receive a second data bit, among the plurality of data bits, from the memory controller 200 while performing the program voltage apply operation.

In an embodiment, the memory device 100 may perform a program voltage apply operation based on the first data bit and the second data bit after receiving the second data bit.

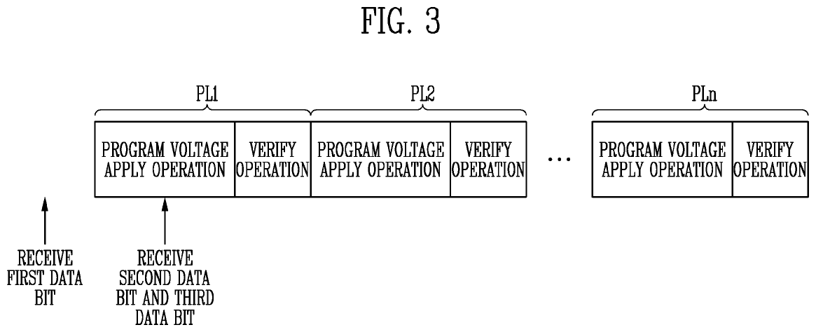

Meanwhile, although, in FIG. 1, the memory device 100 is described as receiving two data bits, the present disclosure is not limited thereto. In an example, the memory device 100 may receive two or more data bits while performing the program voltage apply operation based on the first data bit. In an example, the memory device 100 may receive two or more data bits, and may receive the remaining data bits while performing a program voltage apply operation based on the two or more bits. These embodiments will be described later with reference to the following FIGS. 3 to 6.

FIG. 2 is a diagram illustrating a memory device according to an embodiment of the present disclosure.

Referring to FIG. 2, the memory device 100 may include a memory cell array 110, a peripheral circuit 120, and control logic 130. The control logic 130 may be implemented as hardware, software, or a combination of hardware and software. For example, the control logic 130 may be a control logic circuit operating in accordance with an algorithm and/or a processor executing control logic code.

The memory cell array 110 includes a plurality of memory blocks BLK1 to BLKz.

The plurality of memory blocks BLK1 to BLKz may be coupled to an address decoder 121 through row lines RL. Here, the row lines RL may include at least one source select line, a plurality of word lines, and at least one drain select line. Each of the memory blocks BLK1 to BLKz may be coupled to a page buffer group 123 through bit lines BLs.

Each of the memory blocks BLK1 to BLKz may include a plurality of memory cells. In an embodiment, the plurality of memory cells may be nonvolatile memory cells. Memory cells coupled to the same word line may be defined as one page.

In an embodiment, each of the plurality of memory cells may store a plurality of data bits. Alternatively, each of the plurality of memory cells may be implemented as a multi-level cell (MLC) in which two bits of data are stored, a triple-level cell (TLC) in which three bits of data are stored, or a quad-level cell (QLC) in which four bits of data are stored. In the present specification, for convenience of description, it is assumed that each of the plurality of memory cells is a triple-level cell. However, the scope of the present disclosure is not limited thereto.

The peripheral circuit 120 may perform a program operation, a read operation, or an erase operation on a selected area of the memory cell array 110 under the control of the control logic 130.

The peripheral circuit 120 may include the address decoder 121, a voltage generator 122, the page buffer group 123, and an input/output circuit 124.

The address decoder 121 is coupled to the memory cell array 110 through the row lines RL.

The address decoder 121 may receive addresses ADDR from the control logic 130. The address decoder 121 may decode a row address, among the received addresses. The address decoder 121 may select at least one of the memory blocks BLK1 to BLKz according to the decoded address.

For example, during a program voltage apply operation, the address decoder 121 may apply a program voltage to a selected word line and apply a program pass voltage having a level lower than that of the program voltage to unselected word lines. During a verify operation, the address decoder 121 may apply a verify voltage to a selected word line and apply a verify pass voltage higher than the verify voltage to unselected word lines.

In an embodiment, the address decoder 121 may decode a column address, among the addresses ADDR received from the control logic 130. The decoded column address may be transferred to the page buffer group 123.

The voltage generator 122 may generate a plurality of voltages using an external supply voltage provided to the memory device 100. For example, the voltage generator 122 may generate various operating voltages that are used for program, read, and erase operations. The generated voltages may be supplied to the memory cell array 110 by the address decoder 121.

The page buffer group 123 may include a plurality of page buffers. The plurality of page buffers may store data received through the bit lines BLs or may sense voltages or currents of the bit lines BLs during a read or verify operation. The plurality of page buffers may transmit/receive data DATA to/from the input/output circuit 124.

For example, during a program operation, the plurality of page buffers may transfer the data DATA, received through the input/output circuit 124, to selected memory cells through the bit lines BLs when a program voltage is applied to a selected word line. The memory cells in a selected page may be programmed based on the received data DATA. During a verify operation, the plurality of page buffers may read page data from the selected memory cells through the bit lines BLs.

The input/output circuit 124 may be coupled to the page buffer group 123 through the data lines DL. The input/output circuit 124 may receive data to be stored DATA from the memory controller during the program operation.

The control circuit 130 may generate various signals for controlling the peripheral circuit 120 in response to commands CMD and addresses ADDR received from the memory controller.

In an embodiment, the control logic 130 may include a program operation controller 131.

The program operation controller 131 may control the program operation of the memory device 100. The program operation may include a plurality of program loops. In an embodiment, the program operation controller 131 may be implemented using hardware, software or a combination of hardware and software. For example, the program operation controller 131 may be a processor for executing circuits, processors, or codes that are operated based on an algorithm.

In an embodiment, the program operation controller 131 may control the peripheral circuit 120 to receive one or more of a plurality of data bits from the memory controller. The program operation controller 131 may control the peripheral circuit 120 to perform a first program loop, among the plurality of loops, based on the one or more data bits.

In an embodiment, the program operation controller 131 may control the peripheral circuit 120 to receive the remaining data bits, other than the one or more of the plurality of data bits, from the memory controller while the first program loop is being performed. The program operation controller 131 may control the peripheral circuit 120 to perform the remaining program loops, other than the first program loop among the plurality of loops, based on the plurality of data bits.

FIG. 3 is a diagram illustrating an example of a program operation according to an embodiment of the present disclosure.

Referring to FIG. 3, the program operation may include a plurality of program loops PL1 to PLn. The memory device 100 may program selected memory cells so that each of the selected memory cells has a threshold voltage corresponding to any one of a plurality of program states by performing the plurality of program loops PL1 to PLn.

Each of the plurality of program loops PL1 to PLn may include a program voltage apply operation of applying a program voltage to the memory cells and a verify operation of verifying whether the memory cells have been programmed by applying verify voltages. Whenever each program loop is performed, the program voltage applied to the memory cells may be increased by a unit voltage. To verify the program states of the plurality of memory cells during the verify operation, verify voltages may be sequentially applied. Memory cells which have passed verification using respective verify voltages may be determined to have target program states, and may then be program-inhibited in a next program loop.

In an embodiment, the input/output circuit 124 may receive a first data bit before the plurality of program loops PL1 to PLn are performed.

During the program voltage apply operation of the first program loop PL1, the address decoder 121 may apply a program-inhibit voltage (e.g., a supply voltage) to the memory cells to be programmed to an erase state based on the first data bit. Threshold voltages of memory cells coupled to a bit line to which the program-inhibit voltage is applied may be maintained. Further, the address decoder 121 may apply a program-enable voltage (e.g., a ground voltage) to the remaining memory cells other than the memory cells to be programmed to the erase state based on the first data bit. Memory cells coupled to a bit line to which the program-enable voltage is applied may have increased threshold voltages. Thereafter, the address decoder 121 may apply the program voltage to the plurality of memory cells. Further, the input/output circuit 124 may apply verify voltages to the plurality of memory cells based on the first data bit.

In an embodiment, the input/output circuit 124 may receive a second data bit and a third data bit from the memory controller while applying the program voltage to the plurality of memory cells in the first program loop PL1. The remaining program loops other than the first program loop PL1 may be performed based on the first to third data bits.

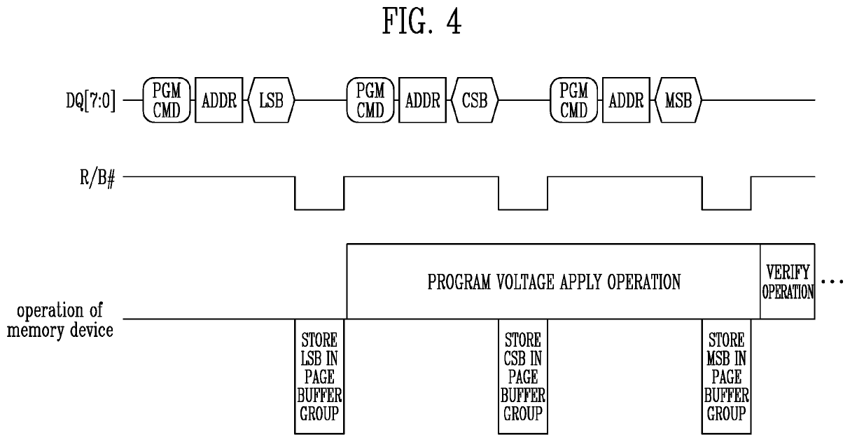

FIG. 4 is a diagram illustrating an example in which a plurality of data bits are received according to an embodiment of the present disclosure.

Referring to FIG. 4, a method in which the memory device 100 receives a plurality of data bits based on the program operation of FIG. 3 is illustrated over time. The memory device 100 may sequentially receive a command, an address, and data from a memory controller through input/output terminals DQ<7:0> of an input/output circuit 124. The case where a read/busy signal R/B # is output at a low level may indicate that the memory device 100 is in a busy state. The case where the read/busy signal R/B # is output at a high level may indicate that the memory device 100 is in a ready state.

The memory device 100 may receive a program command PGM CMD, an address ADDR, and a least significant bit (LSB) of the plurality of data bits from the memory controller. LSB may be the first data bit of FIG. 3.

Thereafter, the memory device 100 may transfer the LSB to a page buffer group 123 and store the LSB therein. Here, the memory device 100 may output a ready/busy signal R/B # at a low level to the memory controller. After storing the LSB in the page buffer group 123, the memory device 100 may output the ready/busy signal R/B # at a high level to the memory controller.

Thereafter, the memory device 100 may perform a program voltage apply operation based on the LSB.

In an embodiment, the memory device 100 may receive a program command PGM CMD, an address ADDR, and a central significant bit (CSB) of the plurality of data bits from the memory controller while performing the program operation based on the LSB. CSB may be the second data bit of FIG. 3.

Thereafter, the memory device 100 may transfer the CSB to the page buffer group 123 and store the CSB therein. Here, the memory device 100 may output the ready/busy signal R/B # at a low level to the memory controller. After storing the CSB in the page buffer group 123, the memory device 100 may output the ready/busy signal R/B # at a high level to the memory controller.

Further, the memory device 100 may receive a program command PGM CMD, an address ADDR, and a most significant bit (MSB) of the plurality of data bits from the memory controller while performing the program operation based on the LSB. MSB may be the third data bit of FIG. 3.

Thereafter, the memory device 100 may transfer the MSB to the page buffer group 123 and store the MSB therein. Here, the memory device 100 may output the ready/busy signal R/B # at a low level to the memory controller. After storing the MSB in the page buffer group 123, the memory device 100 may output the ready/busy signal R/B # at a high level to the memory controller. That is, the page buffer group 123 may store the LSB before the first program loop is performed, and may further store the CSB and the MSB while the first program loop is being performed.

Thereafter, the memory device 100 may perform the verify operation based on the LSB after the program voltage apply operation.

Thereafter, the memory device 100 may perform a program voltage apply operation based on the LSB, CSB, and MSB.

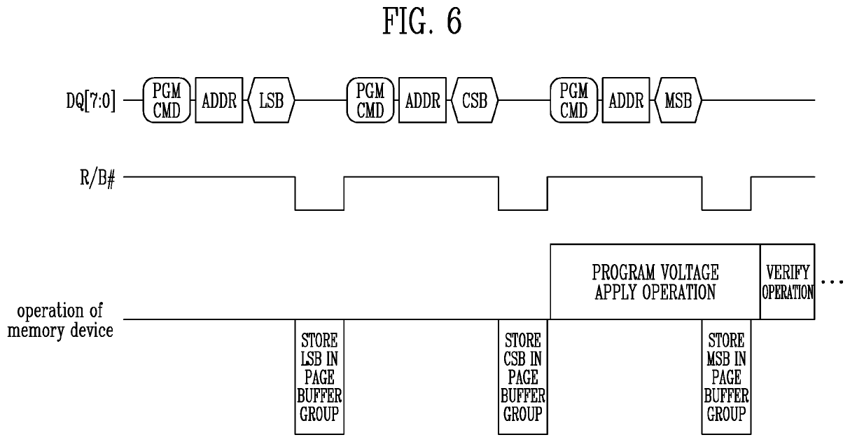

Meanwhile, in the above-described example, although the case where a program command PGM CMD and an address ADDR are received together whenever each data bit is received is described, the present disclosure is not limited thereto. For example, the memory device 100 may receive a program command PGM CMD and an address ADDR in a process of receiving the LSB, and might not receive a program command PGM CMD and an address ADDR in a process of receiving the CSB and the MSB. This may be equally applied to FIG. 6, which will be described later.

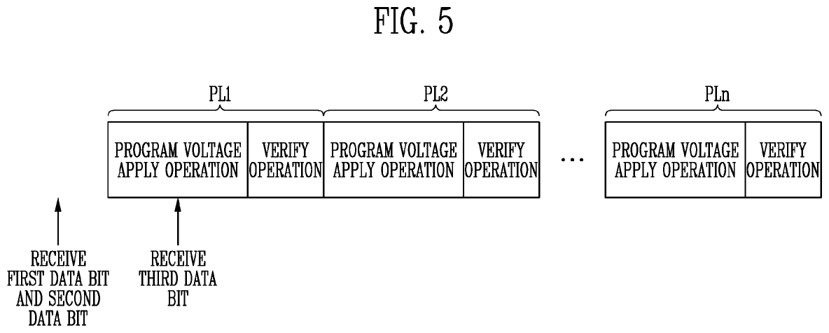

FIG. 5 is a diagram illustrating an example of a program operation according to an embodiment of the present disclosure.

Referring to FIG. 5, apart from the program operation of FIG. 3, an example in which a plurality of data bits are received before a plurality of program loops PL1 to PLn are performed is illustrated.

In an embodiment, an input/output circuit 124 may receive a first data bit and a second data bit before the plurality of program loops PL1 to PLn are performed.

In the program voltage apply operation of the first program loop PL1, an address decoder 121 may apply a program-inhibit voltage to the memory cells to be programmed to an erase state based on the first data bit and the second data bit. Also, the address decoder 121 may apply a program-enable voltage to the remaining memory cells other than the memory cells to be programmed to the erase state based on the first data bit and the second data bit. Thereafter, the address decoder 121 may apply a program voltage to the plurality of memory cells. Further, the input/output circuit 124 may apply verify voltages to the plurality of memory cells based on the first data bit and the second data bit.

In an embodiment, the input/output circuit 124 may receive a third data bit from the memory controller while applying the program voltage to the plurality of memory cells in the first program loop PL1. The remaining program loops other than the first program loop PL1 may be performed based on the first to third data bits.

FIG. 6 is a diagram illustrating an example in which a plurality of data bits are received according to an embodiment of the present disclosure.

Referring to FIG. 6, a method in which the memory device 100 receives a plurality of data bits based on the program operation of FIG. 5 is illustrated over time.

The memory device 100 may receive a program command PGM CMD, an address ADDR, and an LSB of the plurality of data bits from a memory controller. LSB may be the first data bit of FIG. 5.

Thereafter, the memory device 100 may transfer the LSB to a page buffer group 123 and store the LSB therein. Here, the memory device 100 may output a ready/busy signal R/B # at a low level to the memory controller. After storing the LSB in the page buffer group 123, the memory device 100 may output the ready/busy signal R/B # at a high level to the memory controller.

Subsequently, the memory device 100 may receive a program command PGM CMD, an address ADDR, and a CSB of the plurality of data bits from a memory controller. CSB may be the second data bit of FIG. 5.

Thereafter, the memory device 100 may transfer the CSB to the page buffer group 123 and store the CSB therein. Here, the memory device 100 may output the ready/busy signal R/B # at a low level to the memory controller. After storing the CSB in the page buffer group 123, the memory device 100 may output the ready/busy signal R/B # at a high level to the memory controller.

Thereafter, the memory device 100 may perform a program voltage apply operation based on the LSB and the CSB.

In an embodiment, the memory device 100 may receive a program command PGM CMD, an address ADDR, and an MSB of the plurality of data bits from the memory controller while performing the program operation based on the LSB and the CSB. MSB may be the third data bit of FIG. 5.

Thereafter, the memory device 100 may transfer the MSB to the page buffer group 123 and store the MSB therein. Here, the memory device 100 may output the ready/busy signal R/B # at a low level to the memory controller. After storing the MSB in the page buffer group 123, the memory device 100 may output the ready/busy signal R/B # at a high level to the memory controller. That is, the page buffer group 123 may store the LSB and the CSB before the first program loop is performed, and may further store the MSB while the first program loop is being performed.

Thereafter, the memory device 100 may perform a verify operation based on the LSB and the CSB after the program voltage apply operation.

Thereafter, the memory device 100 may perform the program voltage apply operation based on the LSB, CSB, and MSB.

FIG. 7 is a diagram illustrating a storage device according to an embodiment of the present disclosure.

Referring to FIG. 7, a storage device 50 may include a memory device 100 and a memory controller 200 which controls the operation of the memory device 100. The memory device 100 may be the memory device 100 of FIG. 2.

The storage device 50 may be a device which stores data under the control of a host (not illustrated), such as a mobile phone, a smartphone, an MP3 player, a laptop computer, a desktop computer, a game console, a TV, a tablet PC, or an in-vehicle infotainment system.

The storage device 50 may be manufactured as any one of various types of storage devices depending on a host interface that is a scheme for communication with the host. Also, the storage device 50 may be manufactured in any one of various types of package forms.

The memory controller 200 may control the overall operation of the storage device 50.

When power is applied to the storage device 50, the memory controller 200 may run firmware (FW). When the memory device 100 is a flash memory device, the firmware (FW) may include a host interface layer (HIL) which controls communication with the host, a flash translation layer (FTL) which controls communication between the host and the memory device 100, and a flash interface layer (FIL) which controls communication with the memory device 100. In an embodiment, the memory controller 200 may be implemented using hardware, software or a combination of hardware and software. For example, the memory controller 200 may be a processor for executing circuits, processors, or codes that are operated based on an algorithm.

In an embodiment, the memory controller 200 may receive data and a logical block address (LBA) from the host, and may translate the logical block address (LBA) into a physical block address (PBA) indicating the address of memory cells which are included in the memory device 100 and in which data is to be stored. In the present specification, the terms “logical block address (LBA)” and “logical address” may have the same meaning and used interchangeably with each other. In the present specification, the terms “physical block address (PBA)” and “physical address” may have the same meaning and used interchangeably with each other.

In an embodiment, the memory controller 200 may include a memory device controller 210. In an embodiment, the memory device controller 210 may be implemented using hardware, software or a combination of hardware and software. For example, the memory device controller 210 may be a processor for executing circuits, processors, or codes that are operated based on an algorithm.

The memory device controller 210 may control the memory device 100 so that a program operation, a read operation or an erase operation is performed in response to a request received from the host. For example, the memory device controller 210 may communicate with the memory device through a channel.

In an embodiment, the memory device controller 210 may transmit a program command, an address, and a first data bit for the plurality of memory cells to the memory device 100.

In an embodiment, the memory device controller 210 may transmit a second data bit to the memory device 100 while the memory device 100 is programming the first data bit to memory cells corresponding to the address in response to the program command. For example, the memory device 100 may store the first data bit in a page buffer group, and may perform a program operation based on the first data bit. Here, the memory device 100 may store the first data bit in the page buffer group, and thereafter transmit a ready signal to the memory controller 200. After receiving the ready signal from the memory device 100, the memory controller 200 may transmit the second data bit to the memory device 100. Then, after receiving the second data bit, the memory device 100 may program the first data bit and the second data bit to memory cells corresponding to the address.

Meanwhile, in the above-described example, although an embodiment in which the second data bit is transmitted to the memory device while the first data bit is being programmed to the memory cells is described, the present disclosure is not limited thereto. The number of data bits that are transmitted may vary depending on the type of memory cells. For example, the memory controller 200 may transmit a plurality of data bits to the memory device 100 while the first data bit is being programmed. In an example, the memory controller 200 may transmit two or more data bits to the memory device 100, and thereafter transmit the remaining data bits to the memory device 100 while the two or more data bits are being programmed to the memory cells.

In an embodiment, the memory device controller 210 may control two or more memory devices 100. In this case, the memory device controller 210 may control the memory devices 100 depending on an interleaving scheme to improve operating performance. The interleaving scheme may be a scheme for controlling the memory devices 100 so that the operations of at least two memory devices 100 are caused to overlap each other.

In accordance with various embodiments of the present disclosure, there are provided a memory device having improved time required for a program operation, a method of operating the memory device, and a storage device having the memory device.

What is claimed is:

1. A method of operating a memory device, comprising:
receiving a first data bit among a plurality of data bits to be stored in each of a plurality of memory cells from a memory controller;
performing a program voltage apply operation on the plurality of memory cells based on the first data bit; and
receiving a second data bit among the plurality of data bits from the memory controller while performing the program voltage apply operation.

2. The method according to claim 1, wherein performing the program voltage apply operation comprises:
applying a program-inhibit voltage to memory cells to be programmed to an erase state among the plurality of memory cells.

3. The method according to claim 2, wherein performing the program voltage apply operation further comprises:
applying a program voltage to the plurality of memory cells after applying the program-inhibit voltage.

4. The method according to claim 1, further comprising:
applying a verify voltage to the plurality of memory cells based on the first data bit after performing the program voltage apply operation.

5. The method according to claim 1, further comprising:
receiving a program command and an address from the memory controller before receiving the first data bit and receiving the second data bit.

6. The method according to claim 1, further comprising:
performing another program voltage apply operation after performing the program voltage apply operation based on the first data bit, the another program voltage apply operation being performed based on the first data bit and the second data bit.

7. The method according to claim 1, further comprising:
receiving a third data bit among the plurality of data bits after receiving the second data bit from the memory controller while performing the program voltage apply operation.

8. The method according to claim 7, further comprising:
after performing the program voltage apply operation on the plurality of memory cells based on the first data bit, performing another program voltage apply operation on the plurality of memory cells based on the first data bit, the second data bit, and the third data bit.

9. A method of operating a memory device, comprising:
receiving a first data bit among a plurality of data bits to be stored in each of a plurality of memory cells from a memory controller;
receiving a second data bit among a plurality of data bits to be stored in each of a plurality of memory cells from a memory controller after receiving the first data bit;
performing a program voltage apply operation on the plurality of memory cells based on the first data bit and the second data bit; and
receiving a third data bit among the plurality of data bits from the memory controller while performing the program voltage apply operation.

10. A memory device, comprising:
a plurality of memory cells, each configured to store a plurality of data bits;
a peripheral circuit configured to perform a plurality of program loops on the plurality of memory cells; and
a program operation controller configured to control the peripheral circuit to receive one or more data bits among the plurality of data bits from a memory controller, perform a first program loop among the plurality of program loops based on the one or more data bits, and receive remaining data bits, other than the one or more data bits, among the plurality of data bits from the memory controller while the first program loop is being performed.

11. The memory device according to claim 10, wherein the peripheral circuit comprises:
an address decoder configured to apply a program-inhibit voltage to memory cells to be programmed to an erase state among the plurality of memory cells based on the one or more data bits and thereafter apply a program voltage to the plurality of memory cells, in the first program loop.

12. The memory device according to claim 10, wherein the peripheral circuit comprises:
a page buffer group configured to store the one or more data bits before the first program loop is performed, and further store the remaining data bits while the first program loop is being performed.

13. The memory device according to claim 10, wherein the peripheral circuit comprises:
an input and output (input/output) circuit configured to receive the remaining data bits from the memory controller while applying a program voltage to the plurality of memory cells in the first program loop.

14. The memory device according to claim 10, wherein the program operation controller controls the peripheral circuit to perform remaining program loops, other than the first program loop, among the plurality of program loops based on the plurality of data bits.

15. A storage device, comprising:
a memory device including a plurality of memory cells; and
a memory controller configured to transmit a program command, an address, and a first data bit for the plurality of memory cells to the memory device, and transmit a second data bit to the memory device while the memory device is programming the first data bit to memory cells corresponding to the address among the plurality of memory cells in response to the program command.

16. The storage device according to claim 15, wherein the memory device stores the first data bit to a page buffer group and thereafter transmits a ready signal to the memory controller.

17. The storage device according to claim 16, wherein the memory controller receives the ready signal from the memory device and thereafter transmits the second data bit to the memory device.

18. The storage device according to claim 15, wherein the memory device receives the second data bit and thereafter programs the first data bit and the second data bit to memory cells corresponding to the address.
